(19) United States
(12) Patent Application Publication
(10) Pub. No.: US 2021/0013444 A1
(43) Pub. Date: Jan. 14, 2021

(54) ORGANIC ELECTROLUMINESCENT ELEMENT, DISPLAY DEVICE, AND ILLUMINATION DEVICE

(71) Applicant: LUMIOTEC INC., Yonezawa-shi, Yamagata (JP)

(72) Inventor: Junichi TANAKA, Yonezawa-shi (JP)

(73) Assignee: Lumiotec Inc., Yonezawa-shi, Yamagata (JP)

(21) Appl. No.: 16/971,859

(22) PCT Filed: Feb. 19, 2019
(86) PCT No.: PCT/JP2019/005950

§ 371 Date: Aug. 21, 2020

(30) Foreign Application Priority Data
Feb. 23, 2018 (JP) 2018-031238

(51) Int. Cl. H01L 51/50

(52) U.S. Cl. CPC H01L 51/5044; H01L 51/5068; H01L 51/5084; H01L 27/3244; H01L 51/5016; H01L 2251/552; H01L 51/5088

(57) ABSTRACT

An organic EL element (10) has two first light emitting units (13A) which each include a first light emitting layer (16A) having one or two peak wavelengths in a wavelength region of 440 nm to 490 nm. The first light emitting units (13A) are respectively disposed at positions adjacent to inner sides of a first electrode (11) and a second electrode (12), and a substrate is disposed on outer sides of the first electrode (11) and the second electrode (12). White light obtained by light emission of the plurality of light emitting units has a continuous emission spectrum over at least a wavelength region of 380 nm to 780 nm and, in terms of light distribution characteristics of light emitted to the outside of a substrate (18), a luminance of the white light obtained through the substrate (18) has a substantially constant value in an angle range of 0 degrees to 30 degrees from an axis perpendicular to a surface direction of the substrate (18).

### TECHNICAL FIELD

The present invention relates to an organic electroluminescent element, and a display device and an illumination device including the organic electroluminescent element.

### BACKGROUND ART

An organic electroluminescent element (hereinafter, also abbreviated as “organic EL element”) is a self-luminous element having a light emitting layer made of an organic compound between an opposing cathode and an anode. The organic EL element emits light by excitons generated as electrons injected from the cathode side into the light emitting layer and positive holes (holes) injected from the anode side into the light emitting layer are recombined with each other in the light emitting layer when a voltage is applied between the cathode and the anode.

As an organic EL element that realizes high luminance and long life, an element (hereinafter, abbreviated as “MPE element”) having a multiphoton emission structure in which an electrically insulating charge generation layer is disposed between the plurality of light emitting units by considering a light emitting unit including at least one light emitting layer as one unit, is known (for example, refer to PTL 1). In the MPE element, when a voltage is applied between the cathode and the anode, the charges in a charge transfer complex move toward the cathode side and the anode side, respectively. Accordingly, the positive holes are injected into one light emitting unit positioned on the cathode side with the charge generation layer interposed therebetween, and electrons are injected into another light emitting unit positioned on the anode side with the charge generation layer interposed therebetween. In such an MPE element, since light emission from the plurality of light emitting units can be obtained at the same time with the same current amount, it is possible to obtain current efficiency and external quantum efficiency equivalent to the number of light emitting units.

Further, in the MPE element, white light can be obtained by combining the plurality of various light emitting units that emit light of different colors. Therefore, in recent years, development of an MPE element that aims at application to a display device and an illumination device based on the light emission of white light has been advanced. For example, there is known an MPE element suitable for a display device, which generates white light with high color temperature and high efficiency by combining a light emitting unit that emits blue light and a light emitting unit that emits green light and yellow light (for example, refer to PTL 2). In addition, there is known an MPE element suitable for an illumination device, which generates white light with high color temperature and high color rendering by combining a light emitting unit that emits red light and a light emitting unit that emits blue light and yellow light (for example, refer to PTL 3).

The display device and the illumination device have different performance specifications required even for the same white light, and there is a history that the MPE elements having their own structures have been developed. Even in the development of the MPE element that emits white light with high color temperature, for example, as illustrated in PTL 2 and PTL 3, development is focused on a luminous efficiency for a display device, and development is focused on color rendering properties for an illumination device.

However, originally, from the viewpoint of obtaining high-quality white light in both the display device and the illumination device, not white light that is biased to a part of the performance, but white light in which three important indicators of white light such as color temperature, luminous efficiency, and color rendering properties, are in good balance and at good levels, is ideal. More desirably, the luminous efficiency and the color rendering properties are maintained at good levels while realizing a high color temperature of 6500K or higher.

### CITATION LIST

### Patent Literature

PTL 1: JP-A-2003-272860

PTL 2: JP-T-2012-503294

PTL 3: JP-A-2009-224274

### SUMMARY OF INVENTION

### Technical Problem

The present invention has been proposed in view of such circumstances in the related art, and an object thereof is to provide an organic electroluminescent element that is suitable for both a display device and an illumination device by obtaining white light in which all of color temperature, luminous efficiency, and color rendering properties are high, and a display device and an illumination device including the organic electroluminescent element.

### Solution to Problem

In order to achieve the above-described object, the present invention provides the following means.

(1) There is provided an organic electroluminescent element that has a structure in which a plurality of light emitting units having a light emitting layer made of at least an organic compound are laminated with a charge generation layer interposed therebetween, between a first electrode and a second electrode, the element including: two first light emitting units which each include a first light emitting layer having one or two peak wavelengths in a wavelength region of 440 nm to 490 nm; and one second light emitting unit which includes a second light emitting layer having one or two peak wavelengths in a wavelength region of 500 nm to 640 nm, in which the first light emitting units are respectively disposed at positions adjacent to inner sides of a first electrode and a second electrode, in which a substrate is disposed on outer sides of the first electrode and the second electrode, in which white light obtained by light emission of the plurality of light emitting units has a continuous emission spectrum over at least a wavelength region of 380 nm to 780 nm, and, in which, in terms of light distribution characteristics of light emitted to the outside of the substrate, a luminance of the white light obtained through the substrate has a substantially constant value in an angle range of 0 degrees to 30 degrees from an axis perpendicular to a surface direction of the substrate.

(2) In the organic electroluminescent element according to the above-described (1), in terms of light distribution characteristics of light emitted to the outside of the substrate, a spectral radiation luminance of the peak wavelength in the wavelength region of 440 nm to 490 nm may have a substantially constant value in the angle range of 0 degrees to 30 degrees from the axis perpendicular to the surface direction of the substrate.

(3) In the organic electroluminescent element according to the above-described (1) or (2), a correlated color temperature of the white light may be equal to or higher than 6500K.

(4) In the organic electroluminescent element according to any one of the above-described (1) to (3), an average color rendering index (Ra) of the white light may be equal to or greater than 60.

(5) In the organic electroluminescent element according to any one of the above-described (1) to (4), in a special color rendering index (Ri) of the white light, R6 may be equal to or greater than 60.

(6) In the organic electroluminescent element according to any one of the above-described (1) to (5), the first light emitting layer may be configured with a blue fluorescent light emitting layer containing a blue fluorescent substance.

(7) In the organic electroluminescent element according to the above-described (6), blue light obtained from the first light emitting unit including the first light emitting layer may contain a delayed fluorescence component.

(8) In the organic electroluminescent element according to any one of the above-described (1) to (5), the first light emitting layer may be configured with a blue phosphorescent light emitting layer containing a blue phosphorescent substance.

(9) In the organic electroluminescent element according to any one of the above-described (1) to (8), the first light emitting unit and the second light emitting unit may be laminated with the charge generation layer interposed therebetween, and a structure in which the second electrode, the first light emitting unit, the charge generation layer, the second light emitting unit, the charge generation layer, the first light emitting unit, and the first electrode are laminated in this order may be provided.

(10) In the organic electroluminescent element according to any one of the above-described (1) to (9), the charge generation layer may be configured with an electrically insulating layer made of an electron accepting substance and an electron donating substance, and a specific resistance of the electrically insulating layer may be equal to or greater than 1.0×10²Ω·cm.

(11) In the organic electroluminescent element according to the above-described (10), the specific resistance of the electrically insulating layer may be equal to or greater than 1.0×10⁵Ω·cm.

(12) In the organic electroluminescent element according to any one of the above-described (1) to (9), the charge generation layer may be configured with a mixed layer of different substances, and one component of the charge generation layer may form a charge transfer complex by an oxidation-reduction reaction.

(13) In the organic electroluminescent element according to any one of the above-described (1) to (9), the charge generation layer may be configured with a laminated body of an electron accepting substance and an electron donating substance.

(14) In the organic electroluminescent element according to any one of the above-described (1) to (13), the charge generation layer may contain a compound having a structure represented by the following formula (1).

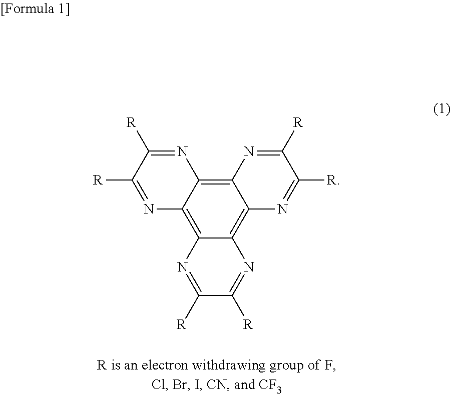

(15) In the organic electroluminescent element according to any one of the above-described (1) to (14), an array of at least three different color filters may further be provided, and the array of at least three different color filters may convert the white light obtained by the light emission of the plurality of light emitting units into light of different colors.

(16) In the organic electroluminescent element according to the above-described (15), the array of the at least three different color filters may be any one selected from a group configured with a stripe array, a mosaic array, a delta array, and a PenTile array.

(17) In the organic electroluminescent element according to the above-described (15) or (16), the at least three different color filters may be a red color filter, a green color filter and a blue color filter, and these three different color filters may have an array of RGB that is alternately arranged.

(18) In the organic electroluminescent element according to the above-described (17), an array of RGBW including the array of RGB may be provided, and the color filter may not be disposed at an array part of W.

(19) In the organic electroluminescent element according to the above-described (18), the array of RGBW may be any one array selected from a group configured with a stripe array, a mosaic array, a delta array, and a PenTile array.

(20) There is provided a display device including: the organic electroluminescent element according to any one of the above-described (15) to (19).

(21) In the display device according to the above-described (20), a base substrate and a sealing substrate may be configured with a flexible substrate and have flexibility.

(22) There is provided an illumination device including: the organic electroluminescent element according to any one of the above-described (1) to (14).

(23) In the illumination device according to the above-described (22), an optical film may be provided on a light extraction surface side of the organic electroluminescent element.

(24) In the illumination device according to the above-described (22) or (23), an average color rendering index (Ra) of the white light may be equal to or greater than 70.

(25) In the illumination device according to the above-described (24), the base substrate and the sealing substrate may be configured with a flexible substrate and have flexibility.

### Advantageous Effects of Invention

According to the present invention, it is possible to provide an organic electroluminescent element that is suitable for both a display device and an illumination device by obtaining white light in which all of color temperature, luminous efficiency, and color rendering properties are high, and a display device and an illumination device including the organic electroluminescent element.

### BRIEF DESCRIPTION OF DRAWINGS

FIG. 1 is a sectional view illustrating a schematic configuration of a first embodiment of an organic EL element of the present invention.

FIG. 2 is a graph illustrating an example of an emission spectrum of white light obtained according to the first embodiment of the organic EL element of the present invention.

FIG. 3 is a sectional view illustrating a schematic configuration of a second embodiment of an organic EL element of the present invention.

FIG. 4 is a sectional view illustrating a schematic configuration of a third embodiment of an organic EL element of the present invention.

FIG. 5 is a sectional view illustrating a schematic configuration of an embodiment of an illumination device of the present invention.

FIG. 6 is sectional view illustrating a schematic configuration of an embodiment of a display device of the present invention.

FIG. 7 is a sectional view illustrating an element structure of an organic EL element of Example.

FIG. 8 is a view illustrating evaluation results of the organic EL element of Example.

FIG. 9 is a view illustrating light distribution characteristics of light emitted into a substrate of the organic EL element of Example.

FIG. 10 is a sectional view illustrating an element structure of an organic EL element of Comparative Example.

FIG. 11 is a view illustrating evaluation results of the organic EL element of Comparative Example.

FIG. 12 is a view illustrating light distribution characteristics of light emitted into a substrate of the organic EL element of Comparative Example.

### DESCRIPTION OF EMBODIMENTS

An organic electroluminescent element, and a display device and an illumination device including the organic electroluminescent element according to the present invention will be described in detail with reference to the drawings.

In addition, in the drawings used in the following description, in order to make it easy to understand the features, there are cases where the parts that are features are enlarged for convenience, and the dimensional ratios of each component are not necessarily the same as the actual ratios. Further, the materials, dimensions, and the like exemplified in the following description are examples, and the present invention is not necessarily limited thereto, and can be appropriately modified and implemented without changing the gist thereof.

### Organic Electroluminescent Element (Organic El Element)

### First Embodiment

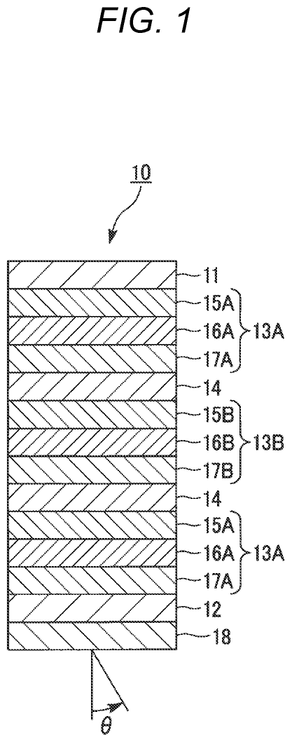

FIG. 1 is a sectional view illustrating a schematic configuration of a first embodiment of an organic EL element of the present invention.

As illustrated in FIG. 1, an organic EL element 10 of the present embodiment is an organic EL element which has a structure in which a plurality of light emitting units 13A and 13B including a light emitting layer made of at least an organic compound are stacked so that a charge generation layer (CGL) 14 are interposed therebetween, between a first electrode 11 and a second electrode 12, and in which white light is obtained as the plurality of light emitting units 13A and 13B emit light.

The organic EL element 10 of the present embodiment has two first light emitting units 13A and one second light emitting unit 13B. The first light emitting units 13A are disposed at positions adjacent to inner sides of the first electrode 11 and the second electrode 12, respectively. Further, a substrate 18 is disposed on an outer side of the second electrode 12. The substrate 18 may be disposed on an outer side of the first electrode 11.

The first light emitting unit 13A is a blue light emitting unit. The blue light emitting unit includes a light emitting layer (first light emitting layer 16A) configured with a blue light emitting layer that emits blue light having one or two peak wavelengths in a blue light wavelength region of 440 nm to 490 nm. The blue light emitting layer may be either a blue fluorescent light emitting layer containing a blue fluorescent substance or a blue phosphorescent light emitting layer containing a blue phosphorescent substance. The blue light obtained from the blue light emitting unit including the blue fluorescent light emitting layer may include a delayed fluorescence component.

The second light emitting unit 13B is an orange light emitting unit. The orange light emitting unit includes a light emitting layer configured with an orange light emitting layer that emits orange light having one or two peak wavelengths over a green to red wavelength region of 500 nm to 640 nm. The orange light emitting layer includes a mixed layer of a green phosphorescent substance and a red phosphorescent substance. The orange light emitting layer may be a stacked body of a green phosphorescent light emitting layer and a red phosphorescent light emitting layer. The stacking order of the green phosphorescent light emitting layer and the red phosphorescent light emitting layer does not matter. Instead of the green phosphorescent substance and the red phosphorescent substance, a green fluorescent substance and a red fluorescent substance may be used. Further, instead of the green phosphorescent light emitting layer and the red phosphorescent light emitting layer, a green fluorescent light emitting layer and a red fluorescent light emitting layer may be used. A single layer of an orange phosphorescent substance or an orange fluorescent substance may be used as the orange light emitting layer.

Yellow to green light emitting units may be used as the second light emitting unit 13B. The yellow to green light emitting units include a light emitting layer configured with yellow to green light emitting layers that emit yellow to green light having one peak wavelength over a green to yellow wavelength region of 500 nm to 590 nm. The yellow to green light emitting layers include a mixed layer of the green phosphorescent substance and a yellow phosphorescent substance. The yellow to green light emitting layers may be a stacked body of the green phosphorescent light emitting layer and a yellow phosphorescent light emitting layer. Furthermore, when the red phosphorescent light emitting layer is stacked, one peak wavelength is added to a red wavelength region of 590 nm to 640 nm, and the second light emitting unit 13B becomes a light emitting unit equivalent to the above orange light emitting unit. The stacking order of the green phosphorescent light emitting layer, the yellow phosphorescent light emitting layer, and the red phosphorescent light emitting layer does not matter.

The organic EL element 10 of the present embodiment has a structure in which the second electrode 12, the first light emitting unit 13A, the charge generation layer 14, the second light emitting unit 13B, the charge generation layer 14, the first light emitting unit 13A, and the first electrode 11 are stacked in this order. In other words, the organic EL element 10 of the present embodiment has an MPE structure in which two first light emitting units 13A and one second light emitting unit 13B are stacked so that the charge generation layer 14 is interposed therebetween.

In the organic EL element 10 of the present embodiment, the white light obtained by the light emission of the first light emitting unit 13A and the second light emitting unit 13B has a continuous emission spectrum over at least a wavelength region of 380 nm to 780 nm. In addition, the organic EL element 10 of the present embodiment has one or two peak wavelengths in the blue wavelength region of 440 nm to 490 nm in this emission spectrum. In addition, the organic EL element 10 of the present embodiment has one or two peak wavelengths in the green to red wavelength region of 500 nm to 640 nm.

A glass substrate or a plastic substrate can be used as the substrate 18.

As the glass substrate, for example, soda lime glass, non-alkali glass, borosilicate glass, silicate glass, or the like is used.

As the plastic substrate, for example, polyethylene terephthalate (PET), polyethylene naphthalate (PEN), polyimide (PI) or the like is used.

As the first electrode 11, it is generally preferable to use a metal having a small work function, an alloy thereof, a metal oxide, or the like. As the metal that forms the first electrode 11, for example, a single metal body including alkali metals such as lithium (Li), alkaline earth metals such as magnesium (Mg) and calcium (Ca), and rare earth metals such as europium (Eu), or an alloy containing these metals, aluminum (Al), silver (Ag), indium (In), or the like can be used.

Further, as described in, for example, “JP-A-10-270171” and “JP-A-2001-102175”, the first electrode 11 may have a configuration in which a metal-doped organic layer is used on the interface between the first electrode 11 and the organic layer. In this case, a conductive material may be used for the first electrode 11, and properties such as work function thereof are not particularly limited.

Further, in the first electrode 11, as described in, for example, “JP-A-11-233262” and “JP-A-2000-182774”, the organic layer that is in contact with the first electrode 11 is made of an organometallic complex compound containing at least one type of ion which is selected from a group made of alkali metal ions, alkaline earth metal ions, rare earth metal ions, and the like. In this case, a metal capable of reducing metal ions contained in the organometallic complex compound to a metal in a vacuum, for example, metals (which is reducible) such as aluminum (Al), zirconium (Zr), titanium (Ti), silicon (Si), and the like, or an alloy containing these metals can be used for the first electrode 11. Among these, Al which is generally widely used as a wiring electrode, is particularly preferable from the viewpoint of ease of deposition, high light reflectance, chemical stability, and the like.

The material of the second electrode 12 is not particularly limited, and as the second electrode 12, in a case where light is extracted from the second electrode 12 side, for example, a transparent conductive material such as indium tin oxide (ITO), indium zinc oxide (IZO), or the like can be used.

Contrary to a case of a general organic EL element, light can also be extracted from the first electrode 11 side by using a metal material or the like for the second electrode 12 and a transparent conductive material for the first electrode 11. For example, by using the method described in JP-A-2002-332567, the transparent conductive material such as ITO or IZO described above can be formed on the first electrode 11 by a sputtering method that does not damage the organic film.

Therefore, when both the first electrode 11 and the second electrode 12 are made transparent, the first light emitting unit 13A, the second light emitting unit 13B, and the charge generation layer 14 are also transparent, and thus, the transparent organic EL element 10 can be manufactured.

Regarding the order of film formation, it is not always necessary to start the film formation from the second electrode 12 side, and the film formation may be started from the first electrode 11 side.

The first light emitting unit 13A includes a first electron transport layer 15A, a first light emitting layer 16A, and a first hole transport layer 17A. In addition, the second light emitting unit 13B includes a second electron transport layer 15B, a second light emitting layer 16B, and a second hole transport layer 17B.

The first light emitting unit 13A and the second light emitting unit 13B can adopt various structures similarly to the known organic EL element of the related art, and can have any stacked structure as long as at least a light emitting layer made of an organic compound is included. In the first light emitting unit 13A and the second light emitting unit 13B, for example, an electron injection layer, a positive hole blocking layer, and the like may be arranged on the first electrode 11 side of the light emitting layer, and a positive hole injection layer, an electron blocking layer, and the like may be arranged on the second electrode 12 side of the light emitting layer.

The first electron transport layer 15A and the second electron transport layer 15B are made of, for example, a known electron transport material of the related art. In the organic EL element 10 of the present embodiment, among the electron transport materials generally used in the organic EL elements, those having a relatively deep highest occupied molecular orbital (HOMO) level are preferable. Specifically, it is preferable to use an electron transport material having a HOMO level of at least approximately 6.0 eV or higher. As such an electron transport material, 4,7-diphenyl-1,10-phenanthroline (BPhen), 2,2′,2″-(1,3,5-benzinitrile)-tris(1-phenyl-1-H-benzimidazole (TPBi) and the like can be used.

The electron injection layer is inserted between the first electrode 11 and the first electron transport layer 15A, between the charge generation layer 14 and the second electron transport layer 15B, and between the charge generation layer 14 and the first electron transport layer 15A in order to improve the injection efficiency of electrons from at least one of the first electrode 11 or the charge generation layer 14. As a material for the electron injection layer, an electron transport material having the same properties as those of the electron transport layer can be used. The electron transport layer and the electron injection layer may be collectively referred to as an electron transport layer.

The hole transport layer is made of, for example, a known positive hole transport material of the related art. The hole transport material is not particularly limited. As the positive hole transport material, it is preferable to use, for example, an organic compound (electron donating substance) having an ionization potential of less than 5.7 eV and having positive hole transporting properties, that is, electron donating properties. As the electron donating substance, for example, an arylamine compound such as 4,4′-bis[N-(2-naphthyl)-N-phenyl-amino]biphenyl(α-NPD) can be used.

The positive hole injection layer is inserted between the second electrode 12 and the first positive hole transport layer 17A, between the charge generation layer 14 and the second positive hole transport layer 17B, and between the charge generation layer 14 and the first positive hole transport layer 17A in order to improve the injection efficiency of positive holes from at least one of the second electrode 12 or the charge generation layer 14. As a material for the hole injection layer, an electron donating material having the same properties as those of the hole transport layer can be used. The hole transport layer and the hole injection layer may be collectively referred to as a hole transport layer.

The blue light emitting layer included in the first light emitting unit 13A includes the blue fluorescent light emitting layer containing the blue fluorescent substance or the blue phosphorescent light emitting layer containing the blue phosphorescent substance. The blue light emitting layer contains, as an organic compound, a host material as a main component and a guest material as a minor component. The blue fluorescent substance or the blue phosphorescent substance corresponds to the guest material. In each case, the blue light emission is due in particular to the properties of the guest material.

As the host material of the blue light emitting layer included in the first light emitting unit 13A, an electron transport material, a hole transport material, or a mixture of both can be used. In the blue fluorescent light emitting layer, for example, a styryl derivative, an anthracene compound, a pyrene compound or the like can be used. Meanwhile, in the blue phosphorescent light emitting layer, for example, 4,4′-biscarbazolylbiphenyl (CBP), 2,9-dimethyl-4,7-diphenyl-9,10-phenanthroline (BCP), or the like can be used.

As a guest material of the blue light emitting layer included in the first light emitting unit 13A, in the blue fluorescent light emitting layer, for example, a styrylamine compound, a fluoranthene compound, an aminopyrene compound, a boron complex, or the like can also be used. Furthermore, 4,4′-bis[4-(diphenylamino)styryl]biphenyl (BDAVBi), 2,7-bis{2-[phenyl(m-tolypamino]-9,9-dimethyl-fluorene-7-yl}-9,9-dimethylfluorene (MDP3FL) and the like can also be used. Meanwhile, in the blue phosphorescent light emitting layer, for example, a blue phosphorescent light emitting material such as Ir(Fppy)₃ and the like can also be used.

Each of the two first light emitting units 13A may be a blue light emitting layer made of the same material or may be a blue light emitting layer made of a different material. In a case where the blue light emitting layer is made of the same material, both the guest material and the host material are made of the same material. However, when the proportion of the guest material in the host material is different, both materials are not made of the same material. Further, in a case where the blue light emitting layer is made of different materials, both are not made of the same material regardless of the proportion of the guest material in the host material.

The light emitting layer included in the second light emitting unit 13B is a mixed layer of the green phosphorescent substance and the red phosphorescent substance in a case where the second light emitting unit 13B is the orange light emitting unit. The mixed layer of the green phosphorescent substance and the red phosphorescent substance contains, as an organic compound, a host material as a main component and a guest material as a minor component, and the green phosphorescent substance and the red phosphorescent substance correspond to the guest material. In each case, the green light emission and the red light emission are due in particular to the properties of the guest material. Further, in a case of forming the light emitting layer of the mixed layer of the green phosphorescent substance and the red phosphorescent substance, it is important to efficiently obtain light emission from both the light emitting materials. For that purpose, it is effective to make the proportion of the red phosphorescent substance less than the proportion of the green phosphorescent substance. This is because, since the energy level of the red phosphorescent substance is lower than the energy level of the green phosphorescent substance, energy transfer to the red phosphorescent substance is likely to occur. Therefore, by making the proportion of the red phosphorescent substance smaller than the proportion of the green phosphorescent substance, it becomes possible to make both the green phosphorescent substance and the red phosphorescent substance efficiently emit light.

Further, the light emitting layer included in the second light emitting unit 13B may be a stacked body of the green phosphorescent light emitting layer and the red phosphorescent light emitting layer in a case where the second light emitting unit 13B is the orange light emitting unit. The green phosphorescent light emitting layer and the red phosphorescent light emitting layer contain, as an organic compound, a host material as a main component and a guest material as a minor component. The green phosphorescent light emitting layer and the red phosphorescent light emitting layer include the green phosphorescent substance and the red phosphorescent light emitting layer, respectively, as guest materials.

In addition, the light emitting layer included in the second light emitting unit 13B may be a mixed layer of the green phosphorescent substance and the yellow phosphorescent substance in a case where the second light emitting unit 13B is the yellow to green light emitting units. The mixed layer of the green phosphorescent substance and the yellow phosphorescent substance contains, as an organic compound, a host material as a main component and a guest material as a minor component, and the green phosphorescent substance and the yellow phosphorescent substance correspond to the guest material. In each case, the green light emission and the yellow light emission are also due in particular to the properties of the guest material. Further, in a case of forming the light emitting layer of the mixed layer of the green phosphorescent substance and the yellow phosphorescent substance, it is important to efficiently obtain light emission from both the light emitting materials. For that purpose, it is effective to make the proportion of the yellow phosphorescent substance less than the proportion of the green phosphorescent substance. This is because, since the energy level of the yellow phosphorescent substance is lower than the energy level of the green phosphorescent substance, energy transfer to the yellow phosphorescent substance is likely to occur. Therefore, by making the proportion of the yellow phosphorescent substance smaller than the proportion of the green phosphorescent substance, it becomes possible to efficiently emit both the green phosphorescent substance and the yellow phosphorescent substance. Further, when all the energy can be transferred to the yellow phosphorescent substance, only the yellow phosphorescent substance can efficiently emit light.

Further, the light emitting layer included in the second light emitting unit 13B may be a stacked body of the green phosphorescent light emitting layer and the yellow phosphorescent light emitting layer, in a case where the second light emitting unit 13B is the yellow to green light emitting units. The green phosphorescent light emitting layer and the yellow phosphorescent light emitting layer contain, as an organic compound, a host material as a main component and a guest material as a minor component. The green phosphorescent light emitting layer and the yellow phosphorescent light emitting layer include the green phosphorescent substance and the yellow phosphorescent light emitting layer, respectively, as guest materials.

In addition, the light emitting layer included in the second light emitting unit 13B may a layer in which the red phosphorescent light emitting layer is further stacked on the mixed layer of the green phosphorescent substance and the yellow phosphorescent substance or the stacked body of the green phosphorescent light emitting layer and the yellow phosphorescent light emitting layer, in a case where the second light emitting unit 13B is the yellow to green light emitting units. The red phosphorescent light emitting layer contains, as an organic compound, a host material as a main component and a guest material as a minor component. The red phosphorescent light emitting layer includes a red phosphorescent light emitting layer as a guest material.

As the host material of the light emitting layer included in the second light emitting unit 13B, an electron transport material, a hole transport material, or a mixture of both can be used. As the host material of the phosphorescent light emitting layer, specifically, for example, 4,4′-biscarbazolylbiphenyl (CBP), 2,9-dimethyl-4,7-diphenyl-9,10-phenanthroline (BCP), or the like can be used.

The guest material of the light emitting layer included in the second light emitting unit 13B is also referred to as a dopant material. A material that utilizes fluorescent light emission for the guest material is usually called a fluorescent light emitting material. A light emitting layer made of this fluorescent light emitting material is called a fluorescent light emitting layer. Meanwhile, a material that utilizes phosphorescent light emission for the guest material is usually called a phosphorescent light emitting material. A light emitting layer made of this phosphorescent light emitting material is called a phosphorescent light emitting layer.

Of these layers, in the phosphorescent light emitting layer, in addition to 75% of triplet excitons generated by recombination of electrons and positive holes, 25% of triplet excitons generated by energy transfer from singlet excitons can also be used, and thus, theoretically, 100% of internal quantum efficiency can be obtained. In other words, excitons generated by recombination of electrons and positive holes are converted into light without causing heat inactivation or the like in the light emitting layer. In fact, in an organometallic complex containing a heavy atom such as iridium or platinum, an internal quantum efficiency close to 100% is achieved by optimizing the element structure.

The guest material of the phosphorescent light emitting layer is not particularly limited. For example, in the red phosphorescent light emitting layer, a red phosphorescent light emitting material such as Ir(piq)₃ or Ir(btpy)₃ can be used. Further, in the green phosphorescent light emitting layer, a green phosphorescent light emitting material such as Ir(ppy)₃ can be used. In addition, in the yellow phosphorescent light emitting layer, a yellow phosphorescent light emitting material such as Ir(bt)₂acac can be used. Further, in the orange phosphorescent light emitting layer, an orange phosphorescent light emitting material such as Ir(pq)₂acac can be used.

The light emitting layer included in the second light emitting unit 13B may be a fluorescent light emitting layer.

In this case, as the host material of the fluorescent light emitting layer, specifically, for example, 4,4′-bis(2,2-diphenylvinyl)-1,1′-biphenyl (DPVBi) or tris(8-hydroxyquinolinolato)aluminum(Alq₃) is used.

The guest material of the fluorescent light emitting layer is not particularly limited. For example, in the red fluorescent light emitting layer, a red fluorescent light emitting material such as DCJTB can be used. Further, in the green fluorescent light emitting layer, a green fluorescent light emitting material such as coumarin 6 can be used. In addition, in the yellow fluorescent light emitting layer, a yellow fluorescent light emitting material such as rubrene can be used. Further, in the orange fluorescent light emitting layer, an orange fluorescent light emitting material such as DCM1 can be used.

As a film forming method of each layer that configures the first light emitting unit 13A and the second light emitting unit 13B, for example, a vacuum vapor deposition method, a spin coating method, or the like can be used.

The charge generation layer 14 is an electrically insulating layer formed of an electron accepting substance and an electron donating substance. The specific resistance of the electrically insulating layer is preferably 1.0×10²Ω·cm or more, and more preferably 1.0×0⁵Ω·cm or more.

The charge generation layer 14 may be configured with a mixed layer of different substances, and one of the components may form a charge transfer complex by an oxidation-reduction reaction. In this case, when a voltage is applied between the first electrode 11 and the second electrode 12, the charges in the charge transfer complex are moved toward the first electrode 11 side and the second electrode 12 side, respectively. Accordingly, the positive holes are respectively injected into the second light emitting unit 13B and the first light emitting unit 13A positioned on the inner side of the first electrode 11 with the charge generation layer interposed therebetween, and the electrons are respectively injected into the second light emitting unit 13B and the first light emitting unit 13A positioned on the inner side of the second electrode 12 with the charge generation layer interposed therebetween. According to this, the light emission from the two first light emitting units 13A and one second light emitting unit 13B can be obtained at the same time with the same current amount, and thus, it is possible to obtain the current efficiency and the external quantum efficiency that are the sum of the luminous efficiencies of the two first light emitting units 13A and one second light emitting unit 13B.

Further, the charge generation layer 14 may be made of a stacked body of the electron accepting substance and the electron donating substance. In this case, when a voltage is applied between the first electrode 11 and the second electrode 12, on the interface between the electron accepting substance and the electron donating substance, the charges generated by the reaction involving electron transfer between the electron accepting substance and the electron donating substance move toward the first electrode 11 side and the second electrode 12 side, respectively. Accordingly, the positive holes are respectively injected into the second light emitting unit 13B and the first light emitting unit 13A positioned on the inner side of the first electrode 11 with the charge generation layer interposed therebetween, and the electrons are respectively injected into the second light emitting unit 13B and the first light emitting unit 13A positioned on the inner side of the second electrode 12 with the charge generation layer interposed therebetween. According to this, the light emission from the two first light emitting units 13A and one second light emitting unit 13B can be obtained at the same time with the same current amount, and thus, it is possible to obtain the current efficiency and the external quantum efficiency that are the sum of the luminous efficiencies of the two first light emitting units 13A and one second light emitting unit 13B.

As the material that forms the charge generation layer, for example, the materials described in JP-A-2003-272860 can be used. Among these materials, the materials described in paragraphs [0019] to [0021] can be preferably used. Further, as the material that forms the charge generation layer, the materials described in paragraphs [0023] to [0026] of “WO 2010/113493” can be used. Among the materials, a strong electron accepting substance (HATCN6) described in paragraph [0059] can be particularly preferably used. In the structure represented by the following formula (1), in a case where the substituent described in R is CN (cyano group), the material corresponds to the above-described HATCN6.

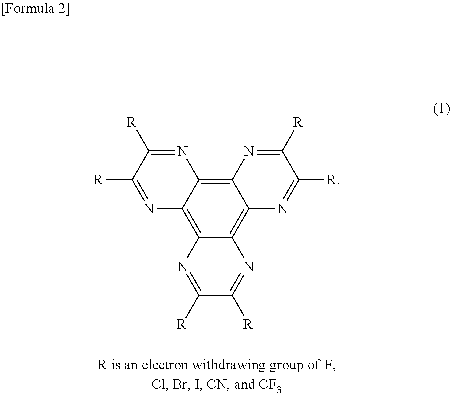

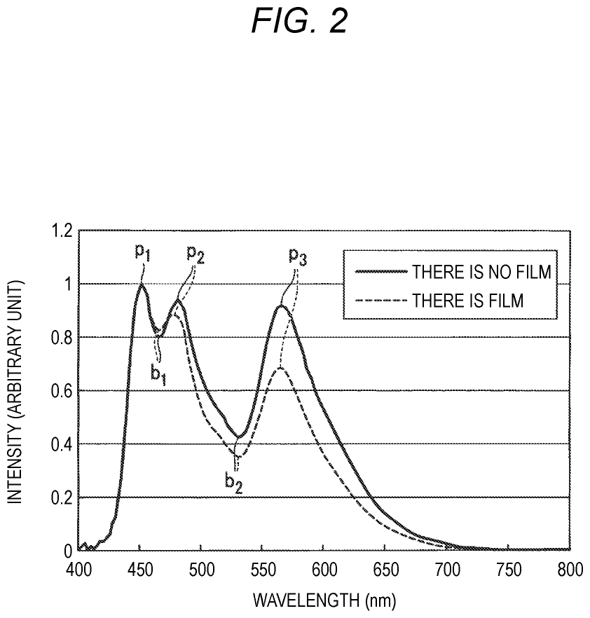

FIG. 2 is a graph illustrating an example of an emission spectrum of the white light obtained by the organic EL element 10 of the present embodiment.

Specifically, as illustrated in FIG. 2, as so-called visible light, the white light obtained by the organic EL element 10 has a continuous emission spectrum S over at least a wavelength region of 380 nm to 780 nm.

The emission spectrum S has one peak wavelength p₁ or two peak wavelengths p₁ and p₂ in the blue wavelength region of 440 nm to 490 nm, and one peak wavelength p₃ or two peak wavelengths p₃ and p₄ in the green to red wavelength region of 500 nm to 640 nm.

The blue light emitted by the blue light emitting layer is an important factor for obtaining the white light having a high color temperature. Specifically, as illustrated in FIG. 2, it is desirable to have any one of one peak wavelength p₁ or two peak wavelengths p₁ and p₂ in the blue wavelength region of 440 nm to 490 nm. Accordingly, the organic EL element 10 of the present embodiment can obtain the white light having a high color temperature. Furthermore, in order to obtain the high-efficiency light emission with the organic EL element of the related art, the light emission in a low color temperature region such as a light bulb color was suitable, and it was difficult to obtain the high-efficiency light emission in warm white color or higher, which has a higher color temperature. Specifically, in a chromaticity range defined by “JIS Z 9112”, the upper limit color temperature of the light bulb color (L) is 3250K, but in the organic EL element 10 of the present embodiment, the high-efficiency white light emission having a correlated color temperature of 3300K or higher can be obtained.

In addition, it is desirable that the emission intensity of one peak wavelength p₁ or two peak wavelengths p₁ and p₂ in the blue wavelength region of 440 nm to 490 nm, is higher than the emission intensity of one peak wavelength p₃ or two peak wavelengths p₃ and p₄ in the green to red wavelength region of 500 nm to 640 nm.

Accordingly, the organic EL element 10 of the present embodiment can further increase the color temperature of the white color. The organic EL element 10 of the present embodiment can obtain the white light having a correlated color temperature of 5000K or higher.

Further, in terms of light distribution characteristics of light emitted to the outside of the substrate 18, in the organic EL element 10 of the present embodiment, the luminance of the white light has a substantially constant value in an angle range of 0 degrees to 30 degrees from the axis perpendicular to the surface direction of the substrate 18. In this angle range, a case where the luminance of the white light is substantially constant indicates that a ratio ((L_{Wmin})/(L_{Wmax})) of (L_{Win}) with respect to (L_{Wmax}) is equal to or greater than 0.9 in a case where the maximum value of the luminance of the white light is (L_{Wmax}) and the minimum value is (L_{Wmin}). In addition, in terms of light distribution characteristics of light emitted to the outside of the substrate 18, a spectral radiation luminance of the peak wavelength in the blue wavelength region of 440 nm to 490 nm has a substantially constant value in the angle range of 0 degrees to 30 degrees from the axis perpendicular to the surface direction of the substrate. In this angle range, a case where the spectral radiation luminance of the peak wavelength in the blue wavelength region indicates that a ratio ((L_{Bmin})/(L_{Bmax})) of (L_{Bmin}) with respect to (L_{Bmax}) is equal to or greater than 0.9 in a case where the maximum value of the spectral radiation luminance of the peak wavelength in the blue wavelength region of 440 nm to 490 nm is (L_{Bmax}) and the minimum value is (L_{Bmin}). In a case where there are two peak wavelengths in the blue wavelength region of 440 nm to 490 nm, the spectral radiation luminance of any wavelength is ((L_{Bmin})/(L_{Bmax})) of 0.9 or more. The light distribution characteristics of the spectral radiation luminance in the blue wavelength region affects the light distribution characteristics of the white light. When ((L_{Bmin})/(L_{Bmax})) is equal to or greater than 0.9, ((L_{Wmin})/(L_{Wmax})) is equal to or greater than 0.9. In addition, in the emission spectrum of the white light, the spectral radiation luminance of the peak wavelength in the green to red wavelength region of 500 nm to 640 nm, which is the wavelength region of the orange light emitted from the second light emitting unit 13B, is lower than the spectral radiation luminance of the peak wavelength in the blue wavelength region of 440 nm to 490 nm, which is the wavelength region of the blue light emitted from the first light emitting unit 13A.

Accordingly, in the organic EL element 10 of the present embodiment, the total luminous flux around the blue light is improved, and thus, the color temperature of the white light can be further increased. The organic EL element 10 of the present embodiment can obtain the white light having a correlated color temperature of 6500K or higher.

It is known that a light emitting unit that emits blue light improves the color temperature in a case of being arranged adjacent to the inner side of the electrode (for example, refer to JP-A-2016-167441). In the organic EL element 10 of the present embodiment, since two first light emitting units 13A that emit blue light are arranged adjacent to each other on the inner sides of each of the first electrode 11 and the second electrode 12, the effect of improving the color temperature is also doubled. In each of the first light emitting units 13A, the color temperature can be suitably improved by optimizing the optical distance to the adjacent electrode.

In addition, the emission intensity of the blue light is an important factor for obtaining the white light having high luminous efficiency. In the organic EL element 10 of the present embodiment, the emission intensity of one peak wavelength p₁ or two peak wavelengths p₁ and p₂ in the blue wavelength region of 440 nm to 490 nm, is at a high level to the extent of being comparable to the emission intensity of one peak wavelength p₃ or two peak wavelengths p₃ and p₄ in the green to red wavelength region of 500 to 640 nm. In a case where the one having the high emission intensity of the emission intensities of the peak wavelengths p₁ and p₂ in the blue wavelength region is (A), and the one having the low emission intensity of the peak wavelengths p₃ and p₄ in the green to red wavelength region is (B), it is desirable that the ratio ((B)/(A)) of (B) with respect to (A) is less than 1.0, and it is more desirable that the ratio is equal to or greater than 0.5 and less than 1.0. In addition, in a case where there is one peak wavelength in the blue wavelength region, the emission intensity of p₁ is (A), and in a case where there is one peak wavelength in the green to red wavelength region, the emission intensity of p₃ is (B).

Accordingly, the organic EL element 10 of the present embodiment can obtain the white light having a high luminous efficiency. The organic EL element 10 of the present embodiment can obtain the white light having an external quantum yield of 20% or higher.

In addition, the presence of the bottom wavelength is an important factor for obtaining the white light having high color rendering properties. The organic EL element 10 of the present embodiment has one bottom wavelength b₂ between one peak wavelength p₁ or two peak wavelengths p₁ and p₂ in the blue wavelength region of 440 nm to 490 nm, and one peak wavelength p₃ or two peak wavelengths p₃ and p₄ in the green to red wavelength region of 500 nm to 640 nm.

Accordingly, the organic EL element 10 of the present embodiment can obtain the white light having high color rendering properties. In the organic EL element 10 of the present embodiment, white light having an average color rendering index (Ra) of 60 or more, R6 of a special color rendering index (Ri) of 60 or more, and R12 of 30 or more can be obtained.

The emission intensity of a peak wavelength b₂ of the bottom wavelength depends on one peak wavelength p₁ or two peak wavelengths p₁ and p₂ in the blue wavelength region of 440 nm to 490 nm, and the emission intensity of one peak wavelength p₃ or two peak wavelengths p₃ and p₄ in the green to red wavelength region of 500 nm to 640 nm.

Therefore, by suitably controlling the emission intensity of the peak wavelengths p₁, p₂, p₃, and p₄, it is possible to simultaneously optimize the luminous efficiency and color rendering properties of the white light.

As described above, the organic EL element 10 of the present embodiment can obtain white light having high color temperature, high luminous efficiency, and high color rendering properties. In addition, since the organic EL element 10 of the present embodiment has an MPE structure in which the first light emitting unit 13A and the second light emitting unit 13B are stacked so that the charge generation layer 14 is interposed therebetween, white light that can perform high-luminance light emission and long-life driving can be obtained.

Accordingly, the organic EL element 10 of the present embodiment can be suitably used for both a display device and an illumination device.

The viewing angle of human reaches approximately 200 degrees horizontally and approximately 125 degrees vertically (50 degrees upward and 75 degrees downward), but in order to obtain the stable vision even when the eyeball moves rapidly, it can be said that an angle range of at least approximately 60 degrees horizontally and approximately 45 degrees vertically is necessary (3D image term dictionary, New Technology Communications (2000), p 124). As described in [0057], in the organic EL element 10 of the present embodiment, in the light distribution characteristics of light emitted to the outside of the substrate 18, the luminance of the white light has a substantially constant value in an angle range of 0 degrees to 30 degrees from the axis perpendicular to the surface direction of the substrate 18. This corresponds to an angle range of 60 degrees horizontally, and at least coincides with to an angle range where the stable vision is obtained. Accordingly, in the organic EL element 10 of the present embodiment, excellent visibility can be obtained with almost no decrease in contrast in the angle range of 60 degrees horizontally. Therefore, the organic EL element 10 of the present embodiment can be suitably used especially for a display device.

### Second Embodiment

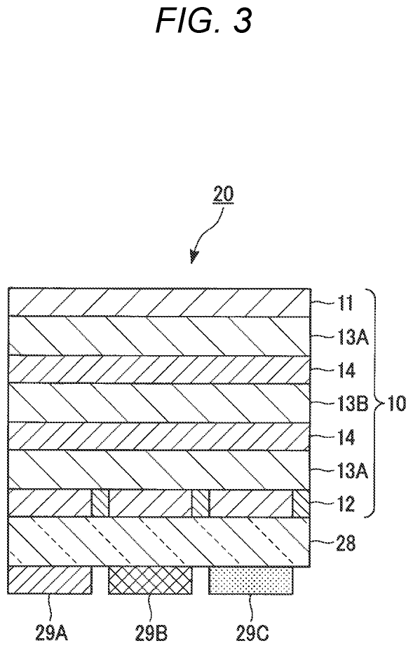

FIG. 3 is a sectional view illustrating a schematic configuration of a second embodiment of the organic EL element of the present invention.

As illustrated in FIG. 3, an organic EL element 20 of the present embodiment has a structure in which a plurality of the organic EL elements 10 of the above-described first embodiment are provided in parallel on a transparent substrate 28. Here, the organic EL element 10 is divided for each second electrode 12 provided on the transparent substrate 28 at a predetermined interval.

Each organic EL element 10 configures a light emitting section of the organic EL element 20, and three different color filters 29A, 29B, and 29C of red, green, and blue are alternately arranged at positions corresponding to the respective light emitting sections via the transparent substrate 28.

The white light obtained from each organic EL element 10 is converted respectively into red light, green light, and blue light through three different color filters 29A, 29B, and 29C (red color filter 29A, green color filter 29B, and blue color filter 29C) of red, green, and blue, and is emitted to the outside.

Accordingly, in the organic EL element 20 of the present embodiment, the white light having high color temperature, high luminous efficiency, and high color rendering properties is used as a starting point, and red light, green light, and blue light having high color purity can be extracted.

The array in which the red color filter 29A, the green color filter 29B, and the blue color filter 29C are alternately arranged forms an array of RGB. The array of RGB may be any one selected from a group configured with a stripe array in which RGB is linearly arranged, a mosaic array in which RGB is arranged in an oblique direction, a delta array in which RGB is triangularly arranged, and a PenTile array in which RG and GB are alternately arranged.

Accordingly, it is possible to realize high-definition and natural-colored image display on the display device.

Above, the organic EL element 20 of the present embodiment can be suitably used for a display device.

In addition, the organic EL element 20 of the present embodiment is not necessarily limited to the above-described configuration, and can be appropriately modified. The organic EL element 20 of the present embodiment may have a structure in which three different color filters of red, green, and blue are installed between the transparent substrate 28 and the second electrode 12.

### Third Embodiment

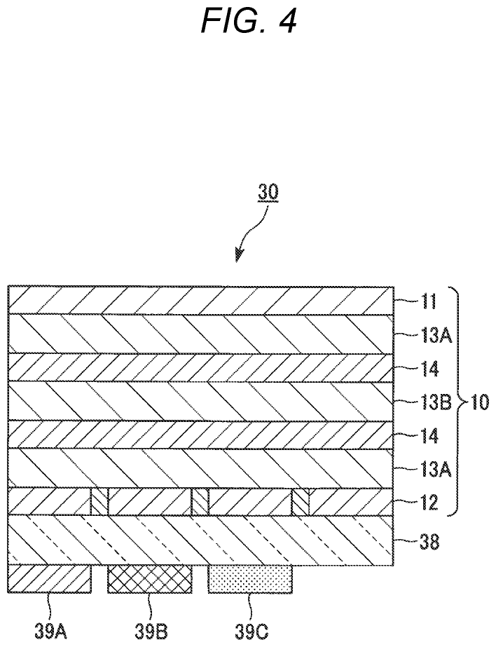

FIG. 4 is a sectional view illustrating a schematic configuration of a third embodiment of the organic EL element of the present invention.

As illustrated in FIG. 4, an organic EL element 30 of the present embodiment has a structure in which a plurality of the organic EL elements 10 of the above-described first embodiment are provided in parallel on a transparent substrate 38. Here, the organic EL element 10 is divided for each second electrode 12 provided on the transparent substrate 38 at a predetermined interval.

Each organic EL element 10 configures a light emitting section of the organic EL element 30, and three different color filters 39A, 39B, and 39C of red, green, and blue and a section where there is no color filter are alternately arranged at positions corresponding to the respective light emitting sections via the transparent substrate 38.

The white light obtained from each organic EL element 10 is converted respectively into red light, green light, and blue light through three different color filters 39A, 39B, and 39C (red color filter 39A, green color filter 39B, and blue color filter 39C) of red, green, and blue, and is emitted to the outside.

Accordingly, in the organic EL element 30 of the present embodiment, the white light having high color temperature, high luminous efficiency, and high color rendering properties is used as a starting point, and red light, green light, and blue light having high color purity can be extracted.

In addition, in the section where there is no color filter (a part where the red color filter 39A, the green color filter 39B, and the blue color filter 39C are not provided, on the transparent substrate 38 illustrated in FIG. 4), the white light obtained from the organic EL element 10 is emitted to the outside as it is.

The array in which the red color filter 39A, the green color filter 39B, the blue color filter 39C and the section where there is no color filter are alternately arranged, forms an array of RGBW. The array of RGBW may be any one selected from a group configured with a stripe array in which RGBW are linearly arranged, a mosaic array in which RGBW is arranged in an oblique direction, a delta array in which RGBW is triangularly arranged, and a PenTile array in which RG and BW are alternately arranged.

In a case of displaying the white color on a display, in the RGB method described in [0065], when white backlight passes through the color filters of respective colors, the luminance is reduced due to absorption by the color filters. Therefore, it is necessary to increase the light amount of the backlight, which in turn leads to an increase in power consumption of the display.

Meanwhile, in the RGBW method, since there is no color filter in the light emitting section of W, the light emission itself from the white backlight can be effectively used during white color display, there is no reduction in luminance and an operation with low power consumption can be realized.

Accordingly, it is possible to realize both high-definition and natural-colored image display and low power consumption on the display device.

Above, the organic EL element 30 of the present embodiment can be suitably used for a display device.

In addition, the organic EL element 30 of the present embodiment is not necessarily limited to the above-described configuration, and can be appropriately modified. The organic EL element 30 of the present embodiment may have a structure in which three different color filters of red, green, and blue are installed between the transparent substrate 38 and the second electrode 12.

### Illumination Device

An embodiment of an illumination device of the present invention will be described.

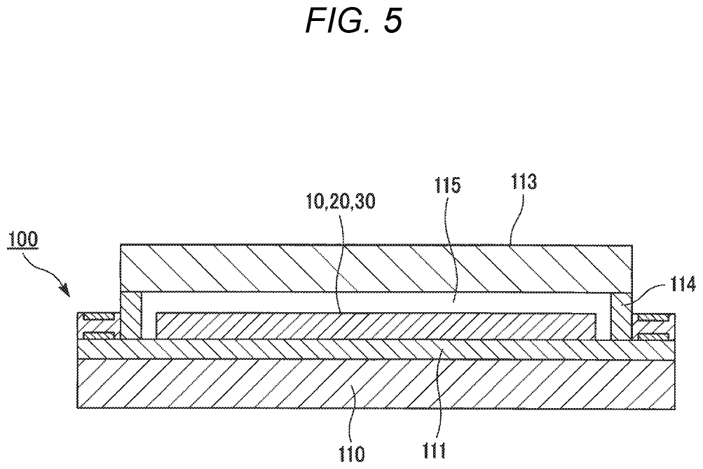

FIG. 5 is a sectional view illustrating a configuration of the illumination device of the present invention. Further, although an example of the illumination device to which the present invention is applied is illustrated here, the illumination device of the present invention is not necessarily limited to such a configuration, and can be appropriately modified.

An illumination device 100 of the present embodiment includes the organic EL element 10 as a light source.

As illustrated in FIG. 5, in the illumination device 100 of the present embodiment, in order to cause the organic EL element 10 to emit light uniformly, a plurality of anode terminal electrodes 111 and a plurality of cathode terminal electrodes (not illustrated) are formed on a peripheral side or at an apex position of a glass substrate 110. In order to reduce the wiring resistance, the surface of the anode terminal electrode 111 and the entire surface of the cathode terminal electrode are covered with solder (base solder). Then, the anode terminal electrode 111 and the cathode terminal electrode uniformly supply the current to the organic EL element 10 from the peripheral side or the apex position on the glass substrate 110. For example, in order to uniformly supply the current to the organic EL element 10 formed in a rectangular shape, the anode terminal electrodes 111 are provided on each side and the cathode terminal electrodes are provided at each apex position. Further, for example, the anode terminal electrodes 111 are provided on the periphery of the L shape including the apex and extending over two sides, and the cathode terminal electrodes are provided at the center of each side.

A sealing substrate 113 is disposed on the glass substrate 110 so as to cover the organic EL element 10 in order to prevent performance deterioration of the organic EL element 10 due to oxygen, water, or the like. The sealing substrate 113 is installed on the glass substrate 110 via the peripheral sealing material 114. A slight gap 115 is secured between the sealing substrate 113 and the organic EL element 10. The gap 115 is filled with a moisture absorbent. Instead of the moisture absorbent, for example, an inert gas such as nitrogen or silicone oil may fill the gap. Further, a gel resin in which a moisture absorbent is dispersed may fill the gap.

In the present embodiment, the glass substrate 110 is used as the base substrate that forms the element, but other than this, it is also possible to use a material such as plastic, metal, or ceramic as the substrate. Further, in the present embodiment, a glass substrate or a plastic substrate can be used as the sealing substrate 113. In a case where a plastic substrate is used for the base substrate and the sealing substrate, the illumination device 100 of the present embodiment has flexibility.

In addition, as the sealing material 114, an ultraviolet curable resin, a thermosetting resin, a laser glass frit or the like having a low oxygen transmittance or a low water transmittance can be used.

The illumination device of the present embodiment can also be configured to include an optical film for improving the luminous efficiency on the light extraction surface side of the organic EL element 10 of the above-described present embodiment.

The optical film used in the illumination device of the present embodiment is for improving the luminous efficiency while maintaining the color rendering properties.

It is generally said that the organic EL element emits light on the inside of a light emitting layer having a refractive index higher than that of the air (refractive index of approximately 1.6 to 2.1), and only approximately 15% to 20% of the light emitted by this light emitting layer can be extracted. This is because the light incident on the interface at an angle greater than the critical angle causes total reflection and cannot be extracted to the outside of the element, the light is totally reflected between the transparent electrode or the light emitting layer and the transparent substrate, the light is guided through the transparent electrode or the light emitting layer, and as a result, the light escapes toward the side surface of the element.

As a method for improving the light extraction efficiency, for example, there are a method of forming irregularities on the surface of the transparent substrate to prevent total reflection on the interface between the transparent substrate and the air (for example, refer to “specification of U.S. Pat. No. 4,774,435”), a method of improving efficiency by giving light condensing properties to the substrate (for example, refer to “JP-A-63-314795”), a method of forming a reflective surface on the side surface of the element (for example, refer to “JP-A-1-220394”), a method of forming an antireflection film by introducing a flat layer having an intermediate refractive index between the substrate and the light emitting body (for example, refer to “JP-A-62-172691”), a method of introducing a flat layer having a refractive index lower than that of the substrate between the substrate and the light emitting body (for example, refer to “JP-A-2001-202827”), a method of forming a diffraction grating between layers (included in a case of being between the substrate and the outside) of any of a substrate, a transparent electrode layer, and a light emitting layer (for example, refer to “JP-A-11-283751”), and the like.

In the illumination device 100, in order to improve the above-described color rendering properties, a structure in which a microlens array or the like is further provided on the surface of the optical film, or a combination with a light condensing sheet is used, and accordingly, by condensing light in a specific direction, for example, in a positive surface direction with respect to an element light emitting surface, it is possible to increase the luminance in the specific direction. Furthermore, in order to control the light radiation angle from the organic EL element, a light diffusion film may be used in combination with the light condensing sheet. As such a light diffusion film, for example, a light diffusion film (light up) manufactured by Kimoto Co., Ltd. can be used.

In addition, the present invention is not necessarily limited to the above-described embodiments, and various modifications can be made without departing from the spirit of the present invention.

Specifically, in the present invention, the organic EL element 10 that can obtain the above-described white light can be suitably used as a light source of the illumination device 100 such as general illumination. Meanwhile, the present invention is not limited to a case where the organic EL element 10 is used as the light source of the illumination device 100, and can be used for various applications such as backlight of a liquid crystal display.

### Display Device

An embodiment of a display device of the present invention will be described.

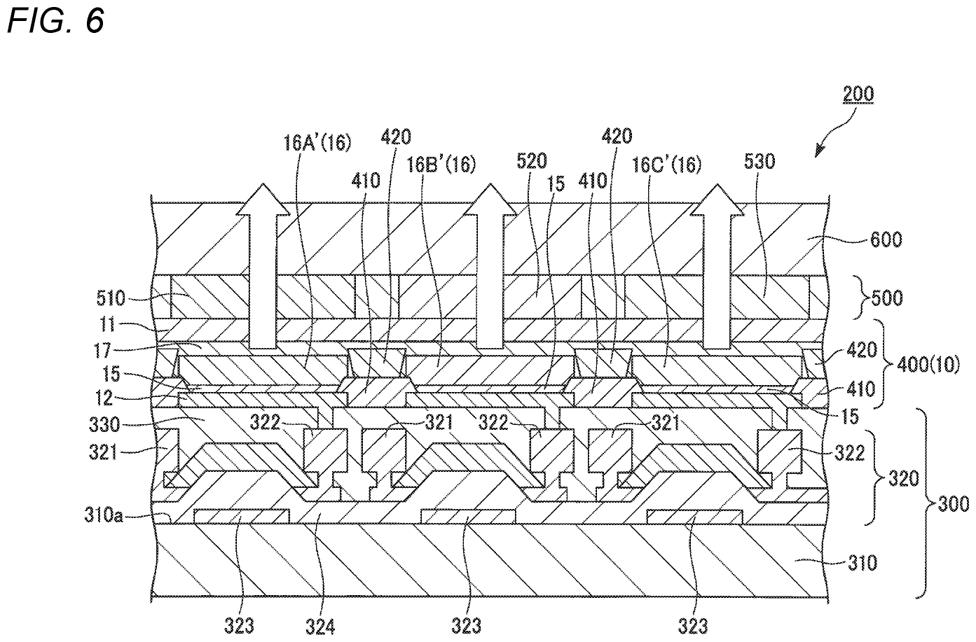

FIG. 6 is a sectional view illustrating a configuration of the display device of the present invention. In FIG. 6, the same components as those of the first embodiment of the organic EL element of the present invention illustrated in FIG. 1 and the second embodiment of the organic EL element of the present invention illustrated in FIG. 3 will be given the same reference numerals, and the description thereof will be omitted. Further, although an example of the illumination device to which the present invention is applied is illustrated here, the display device of the present invention is not necessarily limited to such a configuration, and can be appropriately modified.

In a display device 200 of the present embodiment, as the light source, for example, as described above, the light emitting layer 16 includes the organic EL element 10 provided with a first light emitting section 16A′, a second light emitting section 16B′, and a third light emitting section 16C′.

The display device 200 of the present embodiment is a top emission type and an active matrix type.

As illustrated in FIG. 6, the display device 200 of the present embodiment includes a TFT substrate 300, an organic EL element 400, a color filter 500, and a sealing substrate 600. The display device 200 of the present embodiment has a stacked structure in which the TFT substrate 300, the organic EL element 400, the color filter 500, and the sealing substrate 600 are stacked in this order.

The TFT substrate 300 includes a base substrate 310, a TFT element 320 provided on one surface 310a of the base substrate 310, and a flattening film layer (protection layer) 330 provided on the one surface 310a of the base substrate 310 so as to cover the TFT element 320.

Examples of the base substrate 310 include a glass substrate, a flexible substrate made of plastic, and the like.

The TFT element 320 is provided on a source electrode 321, a drain electrode 322, a gate electrode 323, a gate insulating layer 324 formed on the gate electrode 323, and a channel region which is provided on the gate insulating layer 324 and is in contact with the source electrode 321 and the drain electrode 322.

The organic EL element 400 has the same configuration as that of the organic EL element 10.

The light emitting layer 16 of the organic EL element 400 includes the first light emitting section 16A′ that emits red light, the second light emitting section 16B′ that emits green light, and the third light emitting section 16C′ that emits blue light.

Between the first light emitting section 16A′ and the second light emitting section 16B′, between the second light emitting section 16B′ and the third light emitting section 16C′, and between the third light emitting section 16C′ and the first light emitting section 16A′, a first partition (bank) 410 and a second partition (rib) 420 stacked thereon are provided. The first partition 410 is provided on the flattening film layer 330 of the TFT element 320, and has a tapered shape in which the width gradually narrows as the distance from the flattening film layer 330 increases.

The second partition 420 is provided on the first partition 410 and has an inverse tapered shape in which the width gradually increases as the distance from the first partition 410 increases.

The first partition 410 and the second partition 420 are made of an insulator. Examples of the material that forms the first partition 410 and the second partition 420 include a fluorine-containing resin. Examples of the fluorine compound contained in the fluorine-containing resin include vinylidene fluoride, vinyl fluoride, ethylene trifluoride, and copolymers thereof Examples of the resin contained in the fluorine-containing resin include a phenol-novolac resin, a polyvinylphenol resin, an acrylic resin, a methacrylic resin, and a combination thereof.

The first light emitting section 16A′, the second light emitting section 16B′, and the third light emitting section 16C′ are each provided on the second electrode 12 formed on the flattening film layer 330 of the TFT element 320 via the positive hole transport layer 15.

The second electrode 12 is connected to the drain electrode 322 of the TFT element 320.

The color filter 500 is provided on the first electrode 11 of the organic EL element 400.

The color filter 500 includes a first color filter 510 corresponding to the first light emitting section 16A′, a second color filter 520 corresponding to the second light emitting section 16B′, and a third color filter 530 corresponding to the third light emitting section 16C′.

The first color filter 510 is a red color filter and is disposed so as to oppose the first light emitting section 16A′.

The second color filter 520 is a green color filter and is disposed to oppose the second light emitting section 16B′.

The third color filter 530 is a blue color filter and is disposed so as to oppose the third light emitting section 16C′.

Examples of the sealing substrate 600 include a glass substrate, a flexible substrate made of plastic, and the like. In a case where plastic is used for the base substrate 310 and the sealing substrate 600, the display device 200 of the present embodiment has flexibility.

As illustrated in FIG. 6, in the present embodiment, a case where the light emitting layer 16 of the organic EL element 400 includes the first light emitting section 16A′ that emits red light, the second light emitting section 16B′ that emits green light, and the third light emitting section 16C′ that emits blue light, is exemplified, but the present embodiment is not limited thereto. The light emitting layer 16 may include the first light emitting section 16A′ that emits red light, the second light emitting section 16B′ that emits green light, the third light emitting section 16C′ that emits blue light, and a fourth light emitting section 16D′ (not illustrated) that emits white light. In addition, at a position corresponding to the fourth light emitting section 16D′, no color filter is disposed.

The display device 200 of the present embodiment can obtain white light having high color temperature, high luminous efficiency, and high color rendering properties. Since the display device 200 of the present embodiment includes the organic EL element 20 of the second embodiment, white light having the correlated color temperature of 3300K or higher, the average color rendering index (Ra) of 60 or more, R6 of the special color rendering index (Ri) of 60 or more, and R12 of 30 or more can be obtained.

In addition, the present invention is not necessarily limited to the above-described embodiments, and various modifications can be made without departing from the spirit of the present invention. In the display device 200 of the present embodiment, instead of the organic EL element 20, the organic EL element 30 of the above-described third embodiment can also be used.

### EXAMPLE

Hereinafter, the effects of the present invention will be made more clarified by Examples.

In addition, the present invention is not limited to the following examples, and can be implemented with appropriate modifications within the scope of the invention.

### Example 1

### Manufacturing of Organic EL Element

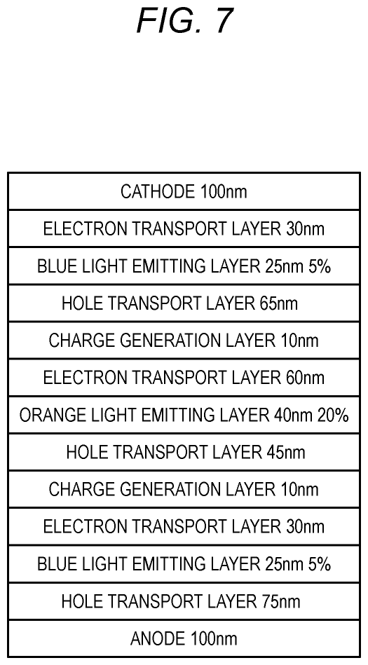

In Example 1, an organic EL element having an element structure illustrated in FIG. 7 was manufactured.

Specifically, first, a soda lime glass substrate having a thickness of 0.7 mm on which an ITO film having a thickness of 100 nm, a width of 2 mm, and a sheet resistance of approximately 20Ω/□ was prepared.

Then, this substrate was ultrasonically cleaned with a neutral detergent, ion exchanged water, acetone, and isopropyl alcohol for 5 minutes each, spin-dried, and further subjected to UV/O₃ treatment.

Next, each of the deposition crucibles (made of tantalum or alumina) in a vacuum deposition apparatus was filled with the configuration material of each layer illustrated in FIG. 7. Then, the above-described substrate is set in the vacuum deposition apparatus, and the deposition crucible is energized and heated in a reduced pressure atmosphere with a vacuum degree of 1×10⁻⁴ Pa or less, and each layer is deposited at a predetermined film thickness at a deposition rate of 0.1 nm/sec. Further, a layer made of two or more materials such as a light emitting layer was co-deposited by energizing the deposition crucible so as to be formed with a predetermined mixing ratio.

In addition, the first electrode was deposited at a deposition rate of 1 nm/sec to a predetermined film thickness.

### Evaluation of Organic EL Element

A power source (trade name: KEITHLEY 2425, manufactured by KEITHLEY) is connected to the organic EL element of Example 1 manufactured as described above, the organic EL element is turned on in the integrating sphere by energizing a constant current of 3 mA/cm², the emission spectrum and the luminous flux value of the organic EL element are measured by a multi-channel spectroscope (trade name: USB2000, manufactured by Ocean Optics Co., Ltd.), and the external quantum efficiency (EQE) (%) of the organic EL element of Example 1 is calculated based on the measurement result.

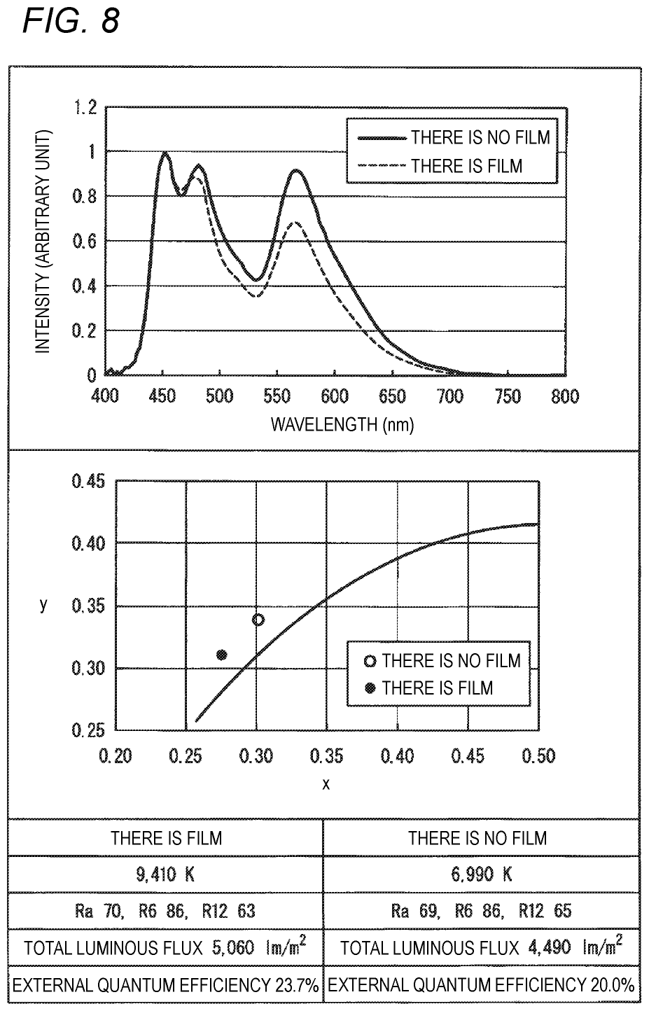

Then, based on the measurement result, the luminescent color was evaluated by the chromaticity coordinates of a CIE color system. In addition, based on the chromaticity coordinates, the luminescent color was classified into the light source colors specified in “JIS Z 9112”. Furthermore, R6 and R12, which are the average color rendering index (Ra) and the special color rendering index (Ri) of the luminescent color, were derived by the method specified in “JIS Z 8726”. The evaluation results summarizing these are illustrated in FIG. 8.

With respect to the organic EL element of Example 1, the luminance and the spectral radiation luminance of white light emitted from this device were evaluated by the following methods.

### Evaluation Method of Luminance and Spectral Radiation Intensity

In order to measure the luminance of white light and the light distribution characteristics of the spectral radiation luminance of blue light, green light, and orange light, a power source (trade name: KEITHLEY 2425, manufactured by KEITHLEY) is connected to the organic EL element, the organic EL element is turned on by energizing the positive current of 3 mA/cm², and in this state, by rotating the jig that fixes the organic EL element at a feed angle of 5 degrees from 0 degrees to 80 degrees, the luminance of the organic EL element at each angle and the spectral radiation luminance in each emission wavelength are respectively measured using a spectral radiance meter (trade name: CS-2000, manufactured by Konica Minolta).

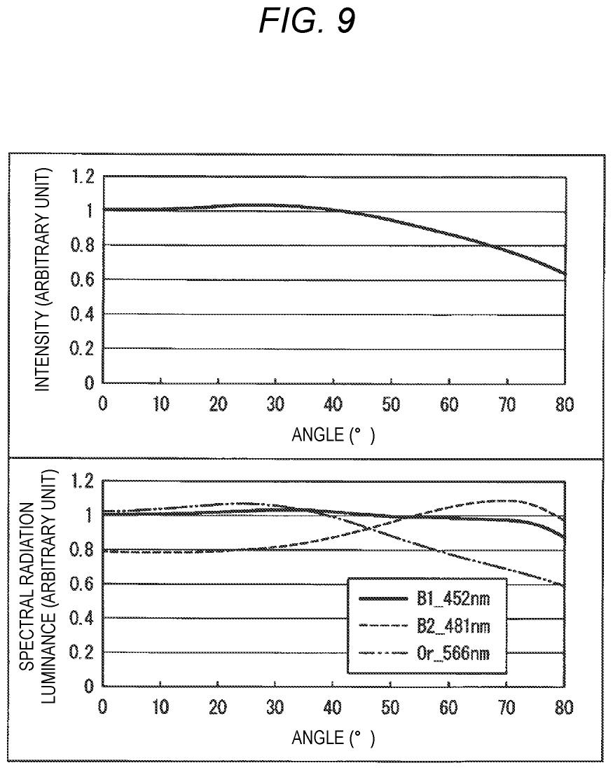

The result thereof is illustrated in FIG. 9.

As illustrated in FIG. 9, in the organic EL element of Example 1, it was found that the luminance of white light had a substantially constant value in the range of the angle of 0 degrees to 30 degrees from the axis perpendicular to the surface direction of the substrate in the light distribution characteristics emitted to the outside of the substrate. In a case where the maximum value of the luminance of the white light is (L_{Wmax}) and the minimum value is (L_{Wmin}), as illustrated in Table 1, L_{Wmax} is 1.030 and L_{Wmin} is 1.000, and a ratio ((L_{Wmin})/(L_{Wmax})) of (L_{Wmin}) with respect to (L_{Wmax}) is 0.971. In addition, in terms of light distribution characteristics of light emitted to the outside of the substrate, it was found that a spectral radiation luminance of the peak wavelength (452 nm, 481 nm) in the blue wavelength region of 440 nm to 490 nm had a substantially constant value in the angle range of 0 degrees to 30 degrees from the axis perpendicular to the surface direction of the substrate. In the peak wavelength of 452 nm, in the angle range, in a case where the maximum value of the spectral radiation luminance is (L_{Bmax}) and the minimum value is (L_{Bmin}), as illustrated in Table 1, L_{Bmax} is 1.027, L_{Bmin} is 1.000, and a ratio ((L_{Bmin})/(L_{Bmax})) of (L_{Bmin}) with respect to (L_{Bmax}) is 0.974. In addition, in the peak wavelength of 481 nm, in the angle range, in a case where the maximum value of the spectral radiation luminance is (L_{Bmax}) and the minimum value is (L_{Bmin}), as illustrated in Table 1, L_{Bmax} is 0.817, L_{Bmin} is 0.790, and a ratio ((L_{Bmin})/(L_{Bmax})) is 0.967. In the spectrum of white light, the spectral radiation luminance of the peak wavelength (566 nm) in the green to red wavelength region of 500 nm to 640 nm becomes a value lower than the spectral radiation luminance of the peak wavelength in the blue wavelength region of 440 nm to 490 nm.

TABLE 1

| | Maximum | Minimum | |
|---|---|---|---|
| Example 1 | value (A) | Value (B) | (B) ÷ (A) |
| White color luminance | 1.030 | 1.000 | 0.971 |
| B1_452 nm | 1.027 | 1.000 | 0.974 |
| B2_481 nm | 0.817 | 0.790 | 0.967 |

Accordingly, the organic EL element of Example 1 can suitably optimize the total luminous flux. As illustrated in FIG. 8, the organic EL element of Example 1 was able to obtain white light with a total luminous flux of 4000 lm/m² or more. Further, by optimizing the total luminous flux, white light having a correlated color temperature of 6500K or higher and Ra of 60 or higher could be obtained. The external quantum efficiency is also at a high level of 20%.

As illustrated in FIGS. 8 and 9, in the organic EL element of Example 1, white light having high color temperature, high luminous efficiency, and high color rendering properties was obtained. Therefore, it has been clarified that the display device and the illumination device provided with the organic EL element of the present invention can be a display device and an illumination device having high color temperature, high luminous efficiency, and high color rendering properties.

### Example 2

The illumination device was manufactured in which an optical film was attached to the light extraction surface (anode) side of the organic EL element of Example 1 described above.

Then, the illumination device of Example 2 was evaluated in the same manner as in Example 1. The evaluation result thereof is illustrated in FIG. 8.

As illustrated in FIG. 8, in the illumination device of Example 2, compared to a case where the optical film was not attached by attaching the optical film to the light extraction surface (anode) side of the organic EL element (indicated by the solid line in the drawing), it is known that the shape is changed. In particular, it was found that the emission intensity in the blue wavelength region of 440 nm to 490 nm is relatively higher than the emission intensity in the green to red wavelength region of 500 nm to 640 nm.

Accordingly, the illumination device of Example 2 can suitably optimize the total luminous flux. The illumination device of Example 2 was able to obtain white light with a total luminous flux of 5000 lm/m² or more. Further, by optimizing the total luminous flux, white light having a correlated color temperature of 9000K or higher and Ra of 60 or higher could be obtained. The external quantum efficiency is also high at 20% or higher.

### Comparative Example 1

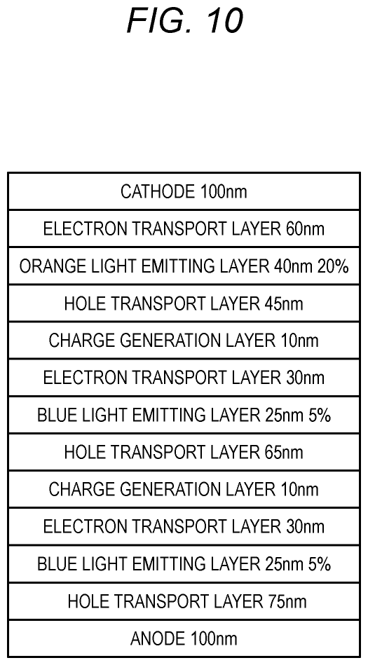

Using the same manufacturing method as that in Example 1, an organic EL element of Comparative Example 1 having the element structure illustrated in FIG. 10 was manufactured.

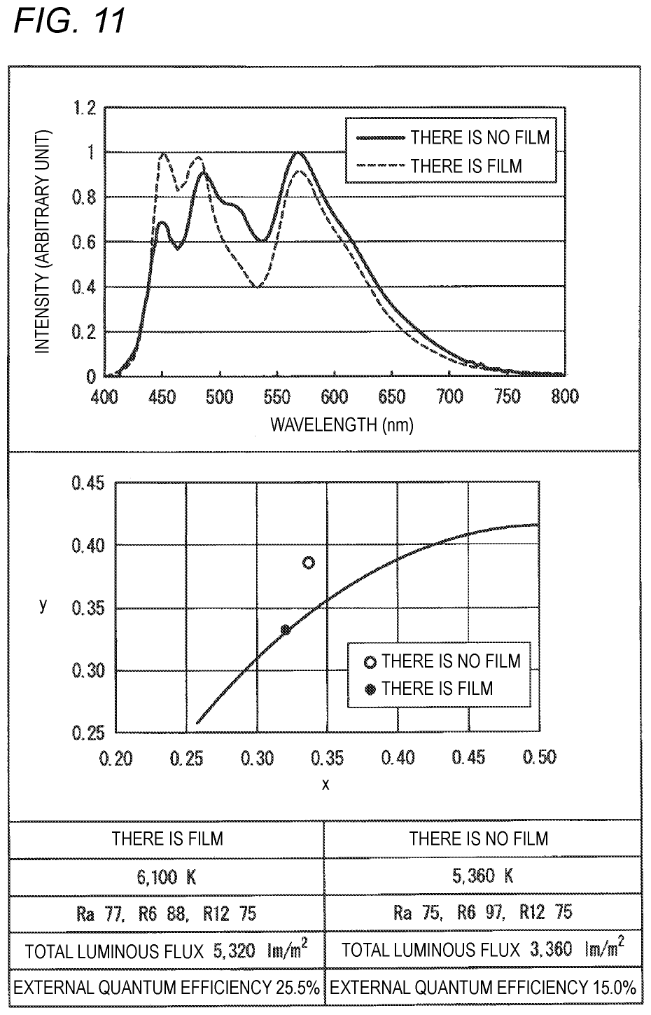

Then, the organic EL element of Comparative Example 1 was evaluated by the same method as those in Example 1. The evaluation result (without film) is illustrated in FIG. 11.

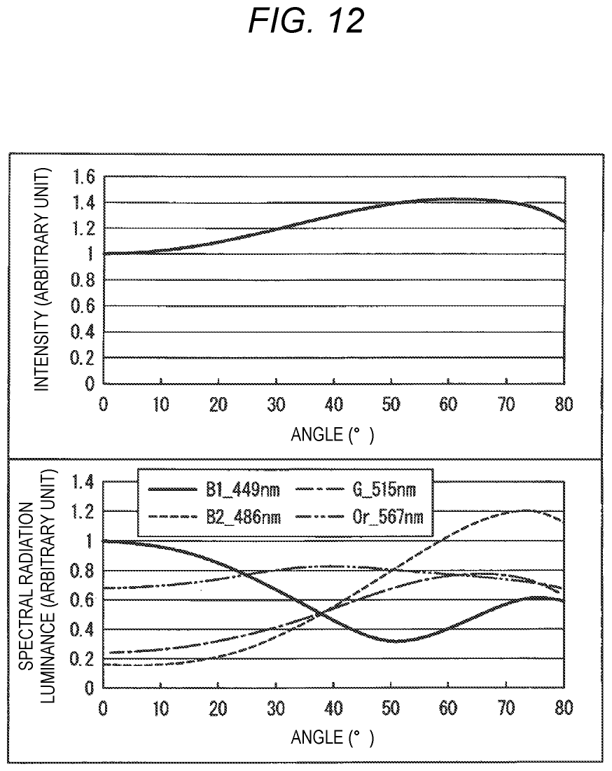

As illustrated in FIG. 12, similar to a case of the organic EL element of Example 1, regarding the spectral radiation luminance of the peak wavelengths (449 nm, 486 nm) in the blue wavelength region of 440 nm to 490 nm, in terms of the light distribution characteristics of light emitted to the outside of the substrate, when viewed in the angle range of 0 degrees to 30 degrees from the axis perpendicular to the surface direction of the substrate, in a case where the maximum value of the luminance of white light is (L_{Wmax}) and the minimum value is (L_{Wmin}), as illustrated in Table 2, L_{Wmax} is 1.195, L_{Wmin} is 1.000, and a ratio ((L_{Wmin})/(L_{Wmax})) of (L_{Wmin}) with respect to (L_{Wmax}) is 0.837. In addition, in the peak wavelength of 449 nm, in a case where the maximum value of the spectral radiation luminance is (L_{Bmax}) and the minimum value is (L_{Bmin}), as illustrated in Table 2, L_{Bmax} is 1.000, L_{Bmin} is 0.679, and a ratio ((L_{Bmin})/(L_{Bmax})) of (L_{Bmin}) with respect to (L_{Bmax}) is 0.679. In addition, in the peak wavelength of 486 nm, in a case where the maximum value of the spectral radiation luminance is (L_{Bmax}) and the minimum value is (L_{Bmin}), as illustrated in Table 2, L_{Bmax} is 0.352, L_{Bmin} is 0.158, and a ratio ((L_{Bmin})/(L_{Bmax})) is 0.449. In all cases, it was clarified that ((L_{Bmin})/(L_{Bmax})) was significantly reduced as compared with the results measured by the organic EL element of Example 1.

TABLE 2

| | Maximum | Minimum | |
|---|---|---|---|
| Comparative Example 1 | value (A) | Value (B) | (B) ÷ (A) |
| White color luminance | 1.195 | 1.000 | 0.837 |
| B1_449 nm | 1.000 | 0.679 | 0.679 |
| B2_486 nm | 0.352 | 0.158 | 0.449 |

In the organic EL element of Comparative Example 1, in terms of light distribution characteristics of light emitted to the outside of the substrate, the spectral radiation luminance of the peak wavelengths (449 nm, 486 nm) in the blue wavelength region of 440 nm to 490 nm is not a substantially constant value in the angle range of 0 degrees to 30 degrees from the axis perpendicular to the surface direction of the substrate, and thus, the total luminous flux is not fully optimized. As illustrated in FIG. 11, the organic EL element of Comparative Example 1 was not able to obtain white light with a total luminous flux of 4000 lm/m² or more. Further, a result in which the color temperature is also lower than that of the organic EL element of Example 1 is obtained.

### Comparative Example 2

The illumination device was manufactured in which an optical film was attached to the light extraction surface (anode) side of the organic EL element of Comparative Example 1 described above.

Then, the illumination device of Comparative Example 2 was evaluated in the same manner as that in Comparative Example 1. The evaluation result thereof is illustrated in FIG. 11.

As illustrated in FIG. 11, in the illumination device of Comparative Example 2, compared to a case where the optical film was not attached by attaching the optical film to the light extraction surface (anode) side of the organic EL element (indicated by the solid line in the drawing), it is known that the shape is changed. In particular, it was found that the emission intensity in the blue wavelength region of 440 nm to 490 nm is relatively higher than the emission intensity in the green to red wavelength region of 500 nm to 640 nm.

As illustrated in FIG. 11, the illumination device of Comparative Example 2 was able to obtain white light with a total luminous flux of 5000 lm/m² or more. This total luminous flux is at a level comparable to the total luminous flux of the illumination device of Comparative Example 1. In addition, Ra was equal to or greater than 70 and the external quantum efficiency was equal to or higher than 20%, and thus, high-quality white light could be obtained. However, the illumination device of Comparative Example 2 does not have a higher color temperature than that of the illumination device of Comparative Example 1. The correlated color temperature is 6100K.

### REFERENCE SIGNS LIST

10, 20, 30: organic EL element
11: first electrode
12: second electrode
13A: first light emitting unit
13B: second light emitting unit
14: charge generation layer
15A: first electron transport layer
16A: first light emitting layer
16B: second light emitting layer
16A′: first light emitting section
16B′: second light emitting section
16C′: third light emitting section
17A: first hole transport layer
17B: second hole transport layer
18: substrate
28, 38: transparent substrate
29A, 39A: red color filter (color filter)
29B, 39B: green color filter (color filter)
29C, 39C: blue color filter (color filter)
100: illumination device
111: anode terminal electrode
113: sealing substrate
114: sealing material
115: gap
200: display device
300: TFT substrate
310: base substrate
320: TFT element
321: source electrode
322: drain electrode
323: gate electrode
324: gate insulating layer
330: flattening film layer
400: organic EL element,
410: first partition
420: second partition
500: color filter
510: first color filter
520: second color filter
530: third color filter
600: sealing substrate

1. An organic electroluminescent element that has a structure in which a plurality of light emitting units having a light emitting layer made of at least an organic compound are stacked so that charge generation layers are interposed therebetween, between a first electrode and a second electrode, the element comprising:
two first light emitting units that each include a first light emitting layer having one or two peak wavelengths in a wavelength region of 440 nm to 490 nm; and
a second light emitting unit that includes a second light emitting layer having one or two peak wavelengths in a wavelength region of 500 nm to 640 nm,
wherein the first light emitting units are respectively disposed at positions adjacent to inner sides of the first electrode and the second electrode,
wherein a substrate is disposed on outer sides of the first electrode and the second electrode,
wherein white light obtained by light emission of the plurality of light emitting units has a continuous emission spectrum over at least a wavelength region of 380 nm to 780 nm, and,
wherein, in terms of light distribution characteristics of light emitted to the outside of the substrate, a luminance of the white light obtained through the substrate has a substantially constant value within an angle range of 0 degrees to 30 degrees from an axis perpendicular to a surface of the substrate.

2. The organic electroluminescent element according to claim 1,
wherein, in terms of light distribution characteristics of light emitted to the outside of the substrate, a spectral radiation luminance of the peak wavelength within the wavelength region of 440 nm to 490 nm has a substantially constant value in the angle range of 0 degrees to 30 degrees from the axis perpendicular to the surface of the substrate.

3. The organic electroluminescent element according to claim 1,
wherein a correlated color temperature of the white light is equal to or higher than 6500K.

4. The organic electroluminescent element according to claim 1,
wherein an average color rendering index (Ra) of the white light is equal to or greater than 60.

5. The organic electroluminescent element according to claim 1,
wherein, in a special color rendering index (Ri) of the white light, R6 is equal to or greater than 60.

6. The organic electroluminescent element according to claim 1,
wherein the first light emitting layer includes a blue fluorescent light emitting layer containing a blue fluorescent substance.

7. The organic electroluminescent element according to claim 6,
wherein blue light obtained from the first light emitting unit including the first light emitting layer contains a delayed fluorescence component.

8. The organic electroluminescent element according to claim 1,
wherein the first light emitting layer includes a blue phosphorescent light emitting layer containing a blue phosphorescent substance.

9. The organic electroluminescent element according to claim 1,
wherein the first light emitting unit and the second light emitting unit are stacked so that the charge generation layer are interposed therebetween, and
wherein a structure in which the second electrode, the first light emitting unit, a first layer of the charge generation layers, the second light emitting unit, a second layer of the charge generation layers, the first light emitting unit, and the first electrode are stacked in this order is provided.

10. The organic electroluminescent element according to claim 1,
wherein each of the charge generation layers includes an electrically insulating layer made of an electron accepting substance and an electron donating substance, and a specific resistance of the electrically insulating layer is equal to or greater than 1.0×10²Ω·cm.

11. (canceled)

12. The organic electroluminescent element according to claim 1,
wherein each of the charge generation layer includes a mixed layer of different substances, and one component of each of the charge generation layers forms a charge transfer complex by an oxidation-reduction reaction.

13. The organic electroluminescent element according to claim 1,
wherein each of the charge generation layers includes a stacked body of an electron accepting substance and an electron donating substance.

14. The organic electroluminescent element according to claim 1,
wherein each of the charge generation layers contains a compound having a structure represented by the following formula (1).

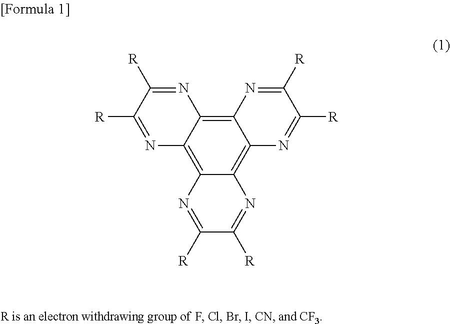

15. The organic electroluminescent element according to claim 1, further comprising:
an array of at least three different color filters,
wherein the array of at least three different color filters converts the white light obtained by the light emission of the plurality of light emitting units into light having different colors.

16. (canceled)

17. The organic electroluminescent element according to claim 15,
wherein the at least three different color filters are a red color filter, a green color filter and a blue color filter, and these three different color filters have an array of RGB that is alternately arranged.

18. (canceled)

19. (canceled)

20. A display device comprising:
the organic electroluminescent element according to claim 15.

21. The display device according to claim 20,
wherein a base substrate and a sealing substrate are made of a flexible substrate and have flexibility.

22. An illumination device comprising:
the organic electroluminescent element according to claim 1.

23. The illumination device according to claim 22,
further comprising an optical film on a light extraction surface side of the organic electroluminescent element.

24. (canceled)

25. The illumination device according to claim 22,
wherein a base substrate and a sealing substrate are made of a flexible substrate and have flexibility.
